(19) United States
(12) Patent Application Publication
(10) Pub. No.: US 2024/0005051 A1
(43) Pub. Date: Jan. 4, 2024

(54) Construction Modeling Systems And Methods For Material Optimization

(71) Applicant: DPR Construction, Redwood City, CA (US)

(72) Inventors: Jerrud Davis, Long Beach, CA (US); Jake Dubenetzky, Murrieta, CA (US); Ray Boff, Ladera Ranch, CA (US)

(21) Appl. No.: 17/855,392

(22) Filed: Jun. 30, 2022

(51) Int. Cl. G06F 30/13

(52) U.S. Cl. CPC G06F 30/13

(57) ABSTRACT

Construction modeling systems and methods for material optimization are disclosed herein. A method can include receiving a building information model comprising walls and hosted wall objects, generating serialized model data, converting the serialized model data into graph structures, the graph structures being determined by identifying wall corners, ceiling vertical transitions, horizontal constraints for ceilings and floors, and hosted conditions for each of the walls, and generating an updated building information model from the graph structures

### CROSS-REFERENCE TO RELATED APPLICATIONS

N/A

### FIELD

The present disclosure pertains to digital construction modeling, and more specifically, but not by way of limitation, to systems and methods for modeling surfaces and optimization of material use.

### SUMMARY

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions. One general aspect includes receiving a building information model comprising walls and hosted wall objects; generating serialized model data; converting the serialized model data into graph structures, the graph structures being determined by identifying wall corners, ceiling vertical transitions, and hosted conditions for each of the walls; and generating a cut sheet for a material based on the graph structures.

In one embodiment, the present disclosure is directed to a system comprising: a processor; and a memory for storing instructions, the processor executing the instructions to: receive a building information model comprising walls and hosted wall objects; generate serialized model data; convert the serialized model data into graph structures, the graph structures being determined by identifying wall corners, ceiling vertical transitions, horizontal constraints for ceilings and floors, and hosted conditions for each of the walls, wherein the graph structures define any one or more of straight edge cuts, cut patterns, top of wall conditions, as well as types of cuts to be milled for a sheet material, wherein a cut sheet is generated for a sheet material based on the updated building information model; and generate an updated building information model from the graph structures.

### BRIEF DESCRIPTION OF THE DRAWINGS

Exemplary embodiments are illustrated by way of example and not limitation in the figures of the accompanying drawings, in which like references indicate similar elements.

FIG. 1 is a schematic diagram of an example environment including a representation of a building information model.

FIG. 2 is a graph representation of a wall and hosted objects.

FIG. 3 illustrates a method for identifying wall conditions.

FIG. 4 is an isometric, vertical representation of the wrapping conditions

FIG. 5 illustrates additional details regarding conditions at end point wraps.

FIG. 6A-6E illustrates the identification, graphing and wrapping of an isolated end point wrap condition.

FIG. 7 illustrates the structure of various hosted condition graphs, their geometric representation, and resultant shapes

FIG. 8A-8D illustrates remainder graphing and analysis.

FIG. 9 illustrates an inside corner wrap condition in graph format, as a geometric representation of the graph and the resultant shapes

FIG. 10 illustrates an outside corner wrap condition in graph format. In general, the outside corner wrap condition is represented by a duplicated vertex type and the vertices in immediate adjacency.

FIG. 11 illustrates a vertical transition condition.

FIG. 12 illustrates a combination of an original BIM model and a generated model.

FIG. 13 illustrates an example cut sheet that can be created from a graph model of the present disclosure.

FIGS. 14A-14E collectively illustrate example calculations pertaining to condition evaluations.

FIGS. 15A-15E collectively illustrate flow diagrams of the present disclosure.

FIGS. 16A-G collectively illustrate an example of different board shape outcomes from programmatically changing the order of operations.

FIGS. 17A-C collectively illustrate potential patterns that could be used to cut wall boards to achieve a flush fit with surrounding conditions.

FIG. 18 is a simplified block diagram of a computing system, in accordance with some embodiments.

### DETAILED DESCRIPTION OF EXAMPLE EMBODIMENTS

### Overview

The present disclosure pertains, in general, to building modeling systems and methods that can be used to ensure an optimized layout of wall sheathing or other similar structures. Moreover, these systems and methods can be used to ensure that building structures are optimally constructed in such a way that material usage is maximized and material loss is minimized.

For context, in a variety of applications, including drywall installation and woodworking, it is common to remove material from the side of a sheet of material to allow for folding and connecting the sheet material at an angle. By removing material from the sheet material, usually in a laterally symmetrical cut up to, but short of, the opposite side, the sheet material can be folded to form a continuous surface.

In corner applications, the folded sheet material may be made permanent with adhesives, eliminating the need for metal corner beads and additional plastering. A sheet material installer can utilize the present disclosure to predetermine sheet size or edge types of the sheet itself, optimizing sheet usage, and reducing installation and finishing time.

By using serialized data from two-dimensional drawings or three-dimensional models that denote the physical description of a building, a computer processor can identify, find, and measure sheet material to be prepared for milling and installation.

Traditionally, the ability for one to find and measure the milled pieces using a printed set of drawings is a slow process, relying on visual identification and manual measurement, which rest on the skill of the person performing the identification and measurement.

By contrast, the present disclosure can include digitizing a blueprint or other similar document (physical or electronic), referred to herein as a building information model (BIM), converting the BIM into a graph model, and cutting a material according to the graph model. As used herein, a graph may be understood to include a plurality of vertices connected by an edge. A weighted graph indicates the distance between two vertices is determined by a real number, the number being the edge's weight. Additional aspects of the present disclosure are provided in greater detail infra.

In some instances, the graph model can be used by a computer numeric controlled (CNC) or other similar device that is used to cut material prior to installation. Any material can be used herein, however, it is advantageous for this process to be used with sheet material such as chipboard, drywall, fiberboard, oriented strand board, particleboard, and plywood, as well as solid lumber or metal sheet goods. The sheet material can be cut and installed to create walls. As used herein, the term “wall” denotes a structure enclosing an area, such as a room, building, or area of land, and may include a sidewall, ceiling, floor, or portion thereof.

### EXAMPLE EMBODIMENTS

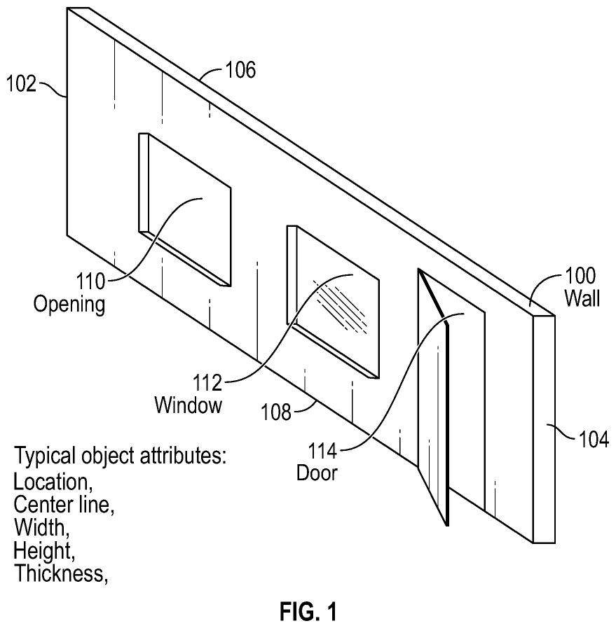

FIG. 1 illustrates an example environment where aspects of the present disclosure can be implemented. For example, FIG. 1 illustrates an example wall 100 that has a right end 102, a left end 104, a top-end 106, and a bottom end 108. To be sure, this wall is an example wall and other walls, which can be more complex in geometrical configuration can be created. Also, the labels of right, left, top, and bottom are contextual and depend on the orientation of the wall. These labels are given for explanatory purposes only. In this example, the wall 100 includes objects such as an opening 110, a window 112, and a door 114. Again, the number, type, and placement of objects on the wall are not limiting.

Walls can be defined by geometrical parameters such as length, height, and thickness. A wall can be made from one or more layers of material. For example, a wall can have two or more outer layers that are placed over a frame structure. Objects can have attributes such as location (placement on the wall), centerline, width, height, and thickness.

A BIM can include data for each wall in a structure. In general, a computer drafting application's drawing file and linked drawing files contain two-dimensional line drawings or three-dimensional models that contains architectural elements such as walls, doors, windows, wall openings, ceilings, ceiling openings, floors, floor openings, structural components such a beams and columns, mechanical, electrical and plumbing components such as mechanical ducts, electrical trays and plumbing lines and all other systems pertinent to the building described.

In some embodiments, the BIM is converted into a serialized XML structure. Each wall and object can be defined by a unique identifier. That is, from the host design application, the building data can be serialized to include properties such as wall start and end point locations, object centerline, width, height, layers of materials and their properties such as thickness, type and applicable elevations on the surface of the wall, wall rating. Ceiling information such as all line segments that describe the perimeter(s) of the ceiling, the layers of materials that comprise the ceiling and their thicknesses. Structural systems locations, type, start and endpoints. The serialized data is written to disk and in-system memory.

Next, the serialized data can be converted into one or more graphs. As used herein, a graph means vertices connected by an edge. A weighted graph means the distance between two vertices is determined by a real number, or its “weight”. For each wall, ceiling, door or other surface(s), a weighted graph data structure is created. A two vertex, single edge graph contains all of the serialized data as object properties of the graph.

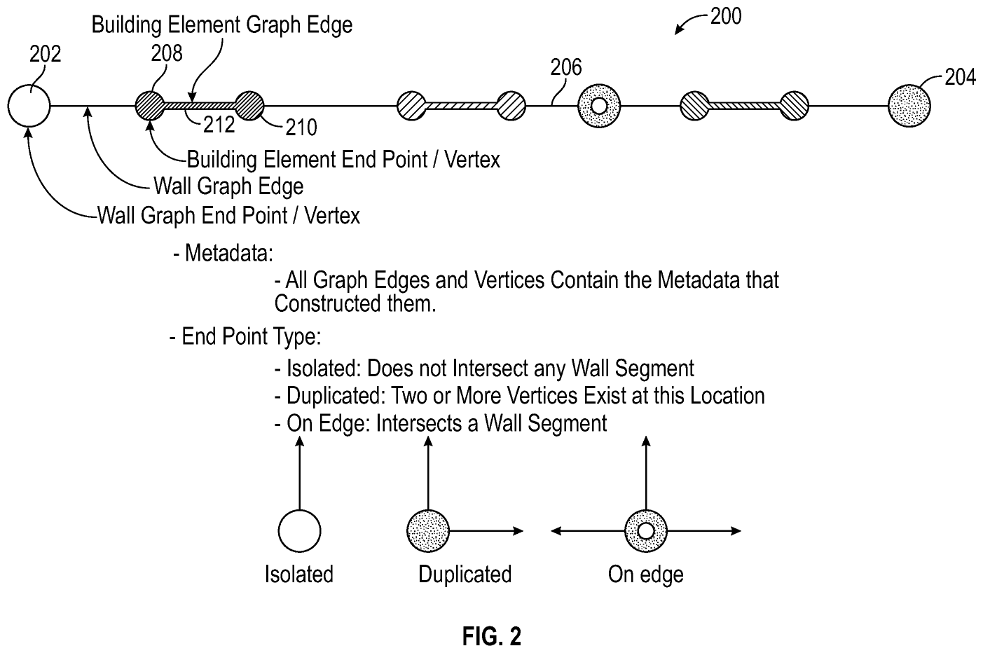

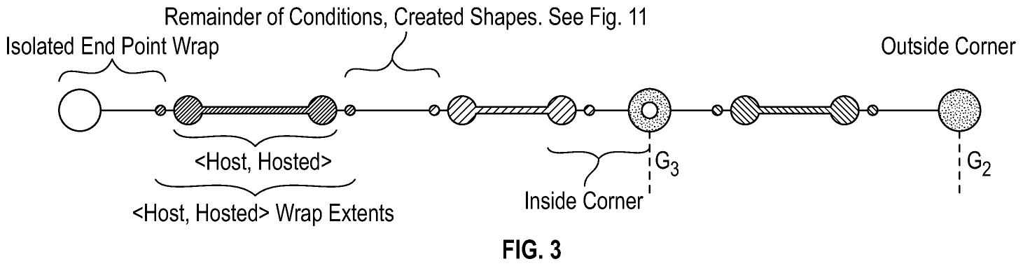

FIG. 2 illustrates an example schematic of a wall graph. A graph data structure can be created for each wall using computational analysis. Example computational analyses methods are disclosed infra. In one example, the end points of each wall define a graph's end point vertices, defining an edge E in graph G. Any building element that is hosted by, intersected by, on the face of, wholly or partially changes a surface or surfaces of a wall can be incorporated into the graph as end point and height vertices. It will be understood that a height vertex includes height data that can be defined as a property or condition of an edge or vertex. These architectural events are defined as a condition.

In the example of FIG. 2, the wall 200 is defined by two wall end points 202 and 204, with a graph edge 206 extending therebetween. Objects in the wall can also be defined by edges and end points. For example, a door can be defined by door end points 208 and 210, with a door graph edge 212. All graph edges and vertices can have metadata assigned thereto. For walls, each end point can be further identified by type such as isolated, duplicated, and on-edge. In this example, end point 202 is isolated and end point 204 is a duplicated edge. It will be understood that an isolated wall end point does not intersect any other wall segment. A duplicated wall end point is created when two or more vertices exist at a location. An on edge wall end point exists when the end point intersects a wall segment. Other walls can be similarly converted into a graph structure. In some instances, different metadata can be used to define ceilings so that they are differentiable from walls.

Architecturally, isolated vertices are ends of walls that do not intersect any other wall. They typically create a cove space. Doubled vertices can be determined by iterating through the list of wall segment endpoints and finding duplicate points. When searching for isolated endpoints, on edge points will be found as well, since confirming isolation reveals on edge conditions.

If a vertex is isolated it cannot be in the set of duplicate vertices and it cannot be in another line segment's length. A vertex is isolated if it satisfies these conditions: (1) it is not in the set of duplicated vertices; (2) it does not exist on any other line segment.

When confirming if a point is isolated and it is found to exist on the edge of another graph, it is understood to be an on edge vertex. With respect to duplicate vertices, since each segment is defined by two end points, any point that occurs twice must be where two segments meet, thus neither are isolated vertices. V_{Duplicates}=V_{StartPoints}∩V_{EndPoints}.

When an on edge vertex is found, add the identifier of the segment that the vertex defines to a list of intersecting segments to the segment being intersected. When confirming graphs, if the intersection list is empty in each edge of the graph, then the graph is not a subgraph.

With regard to uniquely shaped structures, the system can be configured to identify these structures using various techniques. For example, the system can find various shapes, such as “L”, “C”, and “U” shapes or other variants as well as single sided shapes, meaning shapes that do not fold.

Arcuate shapes can be found in all project types, typically as enclosures and around hosted elements. They can be defined as three walls that are bounded by fourth that do not share a common vertex or three walls that are not bound by a fourth wall. They also exist in the geometric representation of the metadata. For example when wrapping the return of an inset window, an “L” shape is produced (see FIG. 804c “C” resultant shapes.

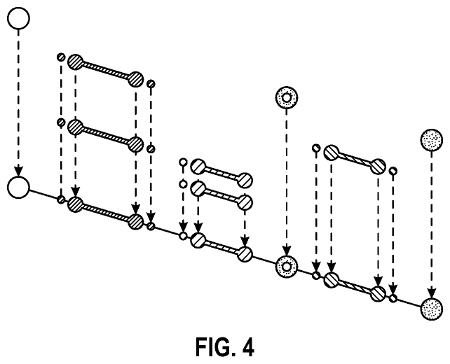

Given a list of line segments defined by two isolated vertices (V₁; V₂), the system can label each of the segment's vertices with the segments ID. Once the graph structures are identified, wrapping conditions can be identified. The system can create shapes defined by a rule set and from geometric conditions, for each condition. The system can then traverse the graph to find adjacent model object vertices. For example, in FIG. 2, conditions for the wall are identified. An isolated end point wrap exists between the door graph vertex 208 and the end point 202 of the wall graph. An outside corner exists where the end point 204 intersects another wall. FIG. 4 is an isometric, vertical representation of the wrapping conditions.

The system can assign V_{DoubledList} as the list of all duplicate vertices in the data set. If an identifier occurs twice in V_{DoubledList}, then both end points are vertices in a graph G. Since Graph G's vertices represent vertices that are duplicated from other line segments, Graph G must be a subgraph of Graph H. Thus, Graph G can be expanded to include adjacent edges.

In some embodiments, if V₁∉V_{DoubledSet} and V₂∉V_{DoubledSet} then they are not shared end points of other line segments and must be either an isolated vertex or a vertex on segment. If V₁ and or V₂ are duplicate or on edge vertices, they can either connect with a common edge or each vertex connects to another line segment, expanding Graph H and making Graph H a subgraph of Graph I. The system can use recursion to explore each vertex and its edge to keep expanding Graph H, but this is not necessary. It will be understood that the graph is only there as an aide to visualize the relationships of line segments, each representing a wall that must be a certain length for a board to completely or partially wrap around it. In some embodiments, a graph can be created based on the set of segments with identical IDs contained within a Node's metadata.

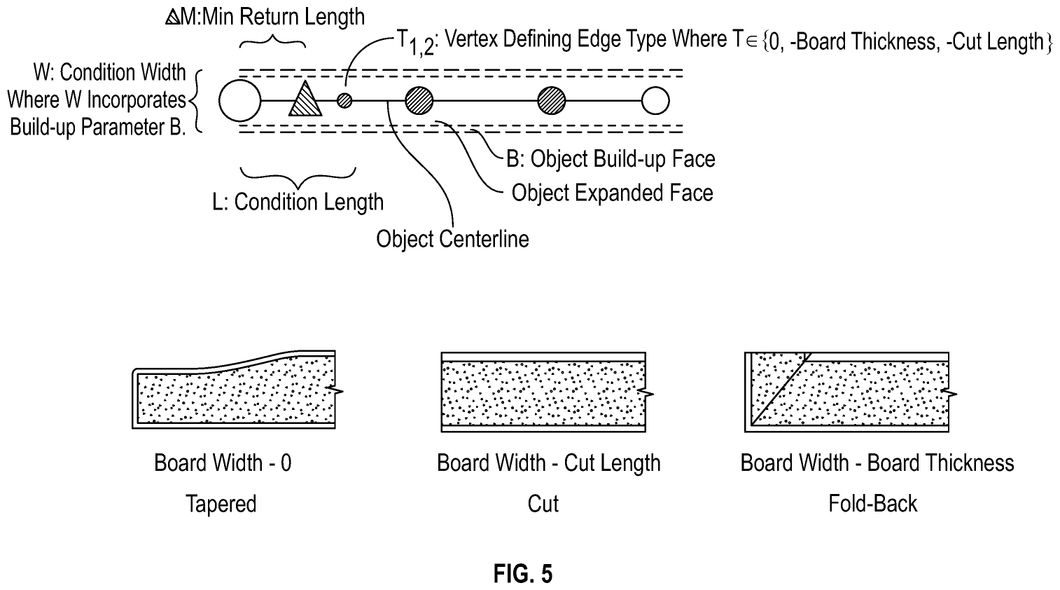

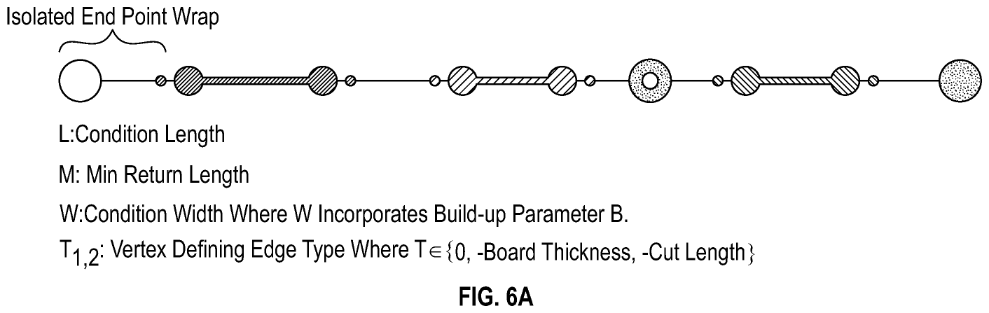

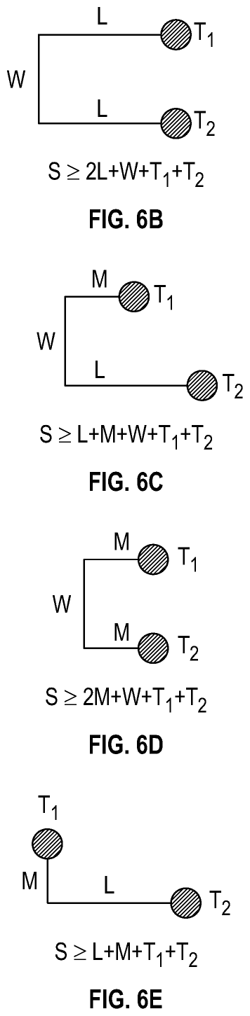

FIG. 5 illustrates additional details regarding conditions W at end point wraps. Additional aspects of the elements illustrated in FIG. 5 are explained in greater detail with respect to FIG. 6. In this example, the thicknesses of wall components can be expressed, with details regarding build up parameters and vertexes T. A vertex T can be defined by parameters such as board thickness, cut length, as well as whether a vertex is tapered, cut, or a fold back. In other words, T defines the edge type required between conditions and joints, where the selection of the type may impact the length of usable board.

FIG. 6 illustrates the identification and graphing of an isolated end point wrap condition. An isolated end point wrap condition represents a wall end that does not terminate at a corner or edge of another surface, resulting in three faces of the wall that need to be wrapped. The system attempts to wrap the condition depending on the variables listed in FIG. 6 and the size of the board material. At the maximum L is a condition length defined by the graph edge adjacent to the isolated end pointM is a minimum return length defined by a user, and W is a condition width where W incorporates a buildup parameter B. T_{1,2} is a vertex defining edge type where T∈{0, −Board Thickness, −Cut Length}. Various isolated vertex wrapping sequences and resultant shapes are illustrated in FIGS. 6B-6E based on the board size S.

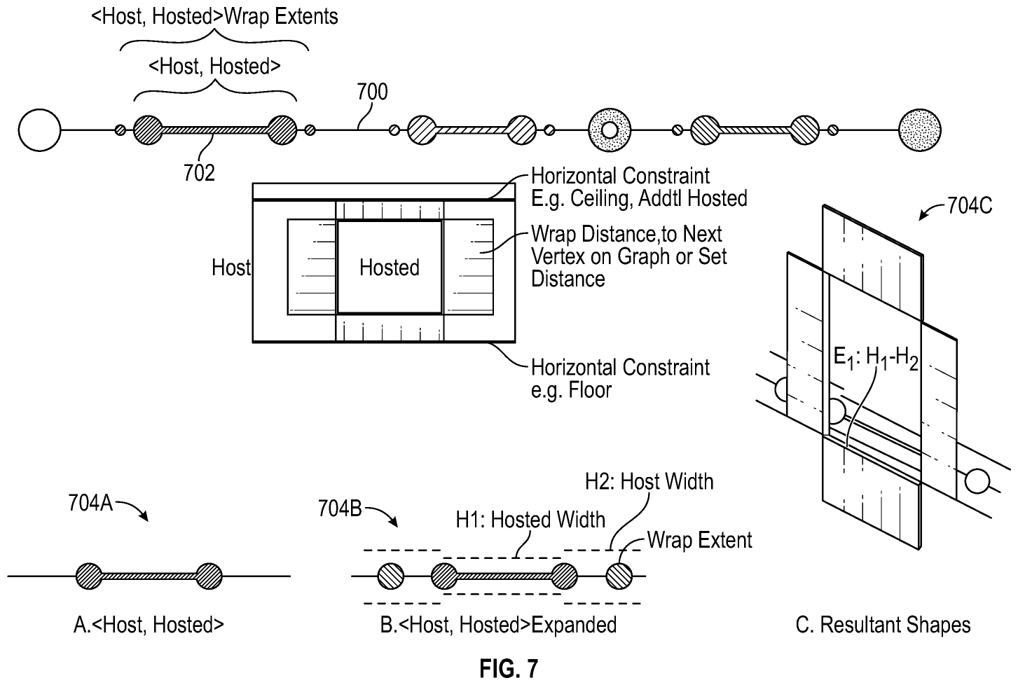

Referring now to FIG. 7, as also illustrated above in FIG. 5, the graph can include <Host,Hosted> conditions. A <Host,Hosted> condition represents a relationship between a building object and its hosting wall (e.g., a door of type A and a wall of type B). Each type of <Host,Hosted> conditions contains a rule or rules defining how to wrap their interior and adjacent faces and preferred edge types. In some instances, one <Host,Hosted> condition can be nested inside another <Host,Hosted> condition.

In this example, the host wall 700 includes a hosted window 702. Horizontal constraints can be set for both ceiling and floor. Wrap distances to adjacent vertexes on a graph can also be included. In this example, four wrap distances are included 704A-704C. An isometric view of the graph is illustrated in 704C.

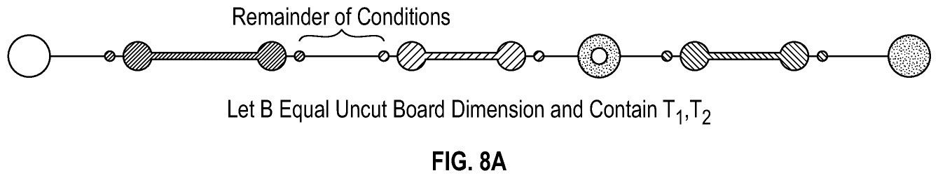

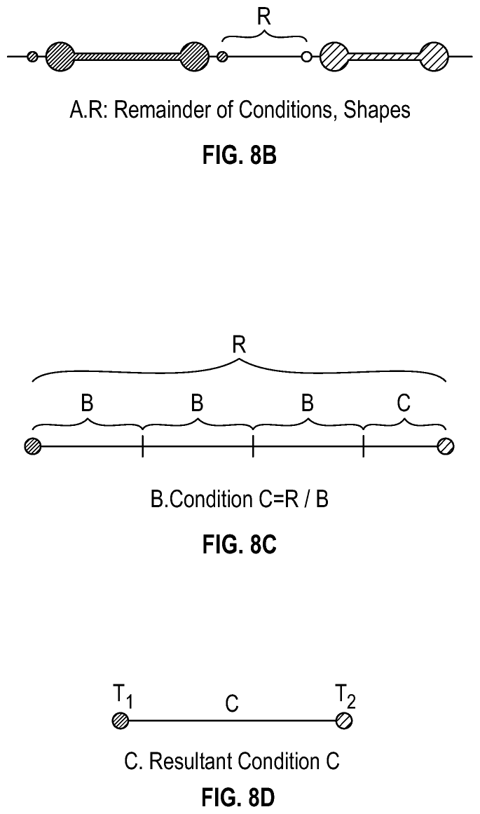

Other conditions can be referred to as remainders. A remainder represents a space between graph vertices that represent end points of objects or joint locations. The remainder spaces become conditions unto themselves, providing an opportunity to calculate the location and length of whole and/or partial boards along their length. As best illustrated in FIGS. 8A-8D, remainders can be identified on a graph 800. In this example, FIG. 8B represents an uncut board dimension that contains T₁, T₂. To be sure, remainder conditions produce single sided shapes (i.e., shapes without a fold). In more detail, FIG. 8B expands the condition R into its components. FIG. 8C defines the meaning of condition C, being distinct from condition B, which is a whole board without modification from the manufacturer. Condition C is distinct from B in that it also contains the metadata of the adjacent vertices and thus can adjust its edge type accordingly. Additionally, edge type combinations have practical ramifications and as such, some combinations are preferred. Condition C can reflect these preferences.

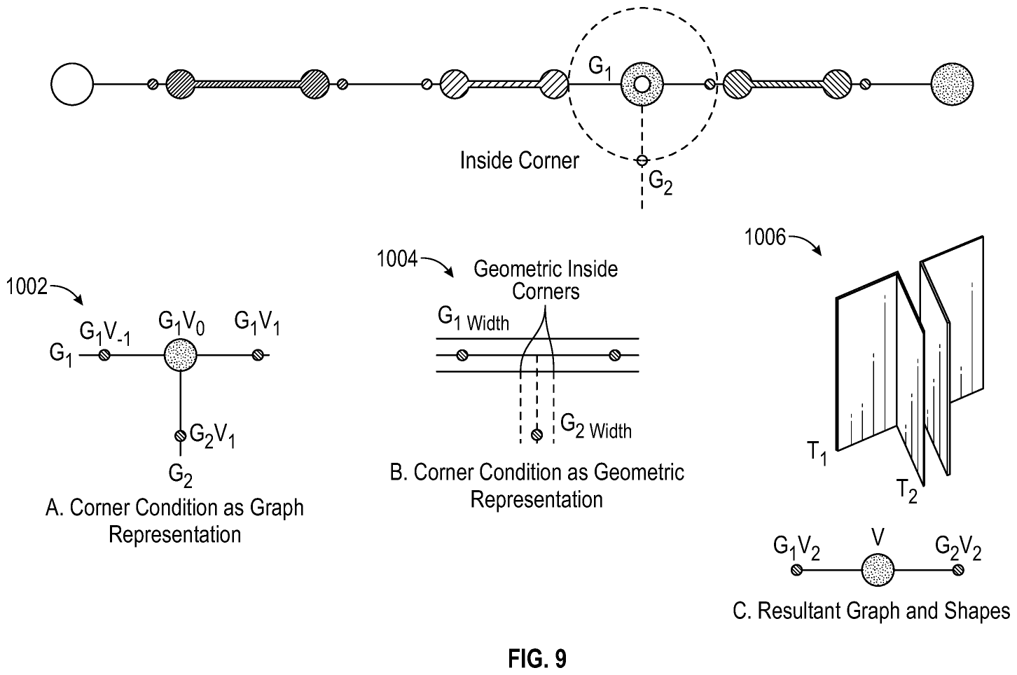

FIG. 9 illustrates an inside corner wrap condition in graph format. A corner condition is illustrated in graph format 1002. FIG. 9 also includes a geometric representation 904, where wall widths are shown. FIG. 9 further includes a resultant graph and isometric view 906 that is the combination of G₁V₂ and G₂V₂ that extends from either side of the vertex V.

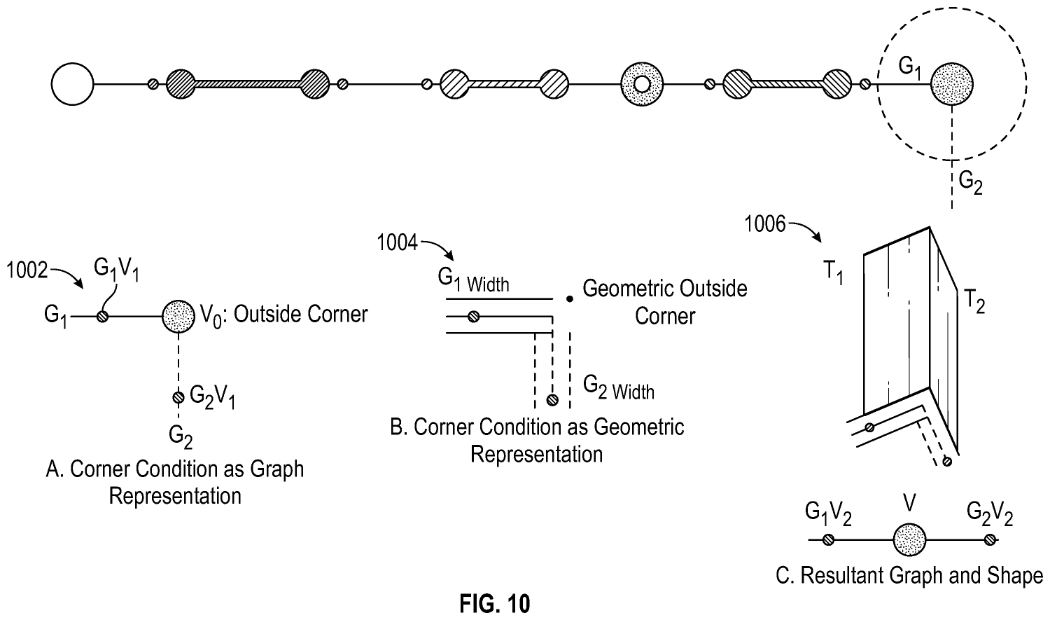

FIG. 10 illustrates an outside corner wrap condition in graph format. In general, the outside corner wrap condition is represented by a duplicated vertex type and the vertices in immediate adjacency along G₁ and G₂. FIG. 10 includes a corner condition as graph representation 1002, a corner condition as geometric representation 1004, and a resultant graph and isometric shape 1006.

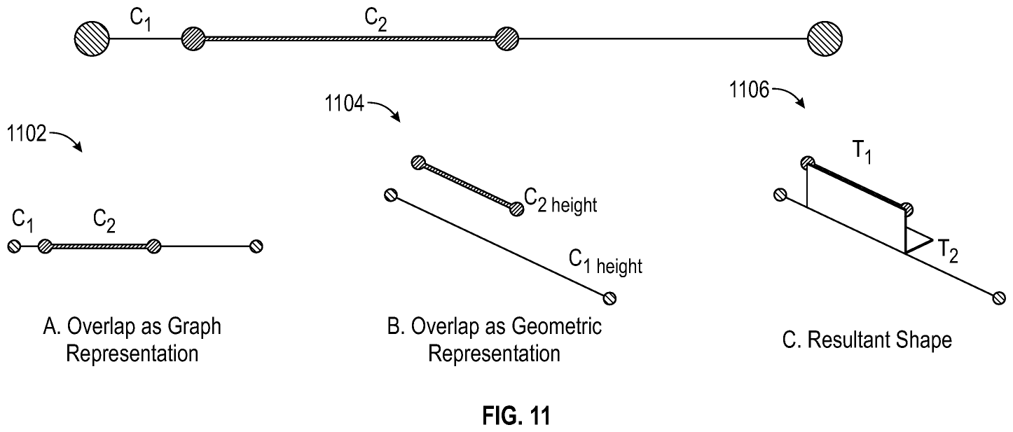

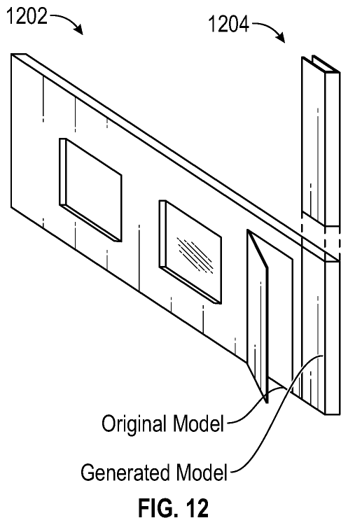

FIG. 11 illustrates a vertical transition condition known colloquially as a soffit. The vertical transition condition is represented by two ceiling edges that require wrapping, and can be identified as the overlapping of their edges and the set intersection of the two line segments. Additional details for computing these vertical transition conditions are found infra. It will be understood that there are methods to find the length of the bottom face of the vertical transition. The algorithms illustrated in FIG. 11 can be used to determine if a type of condition occurs at all and if so, where its extents exist. To find the extent of the bottom face, project the points that define the extents of the vertical transition onto the line segments that define the polygon containing C₁. Given a closed polygon (starting at point A, traversing each point ends at point A), and a polygon without crossing sides, the projected points will coincide in a line segment or segments (if the projection points project onto two sides containing a common vertex) and the distance of the point that was projected (P₀) and the point contained in side S (P₁) is the maximum return distance in the condition. A wrap of the graph can occur as disclosed above. FIG. 11 illustrates an overlap as graph representation 1102, an overlap as geometric representation 1104, and a resultant shape 1106. FIG. 12 illustrates a combination of an original BIM model 1202 and a generated model 1204. In this example, an isolated edge 1206 of a wall 1208 is illustrated.

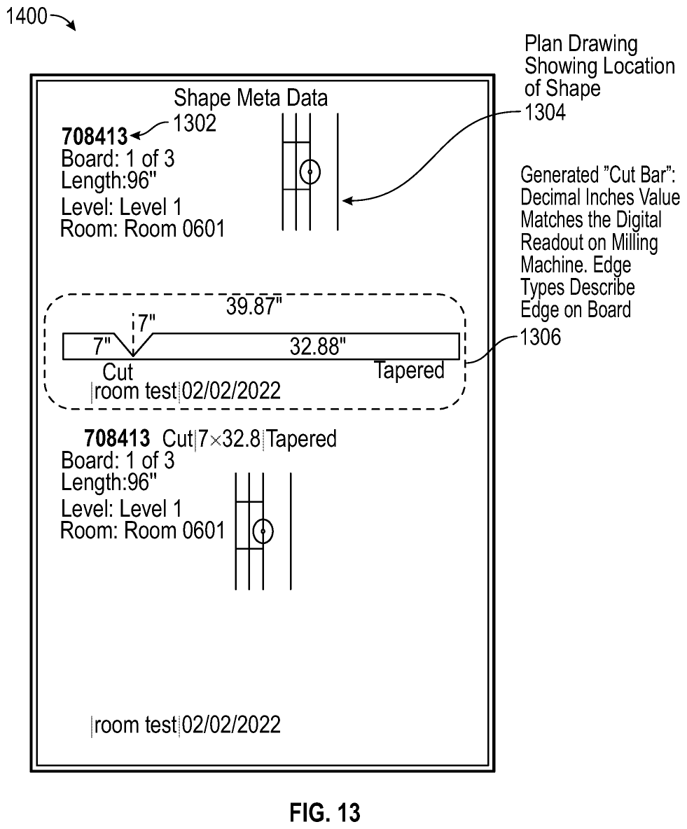

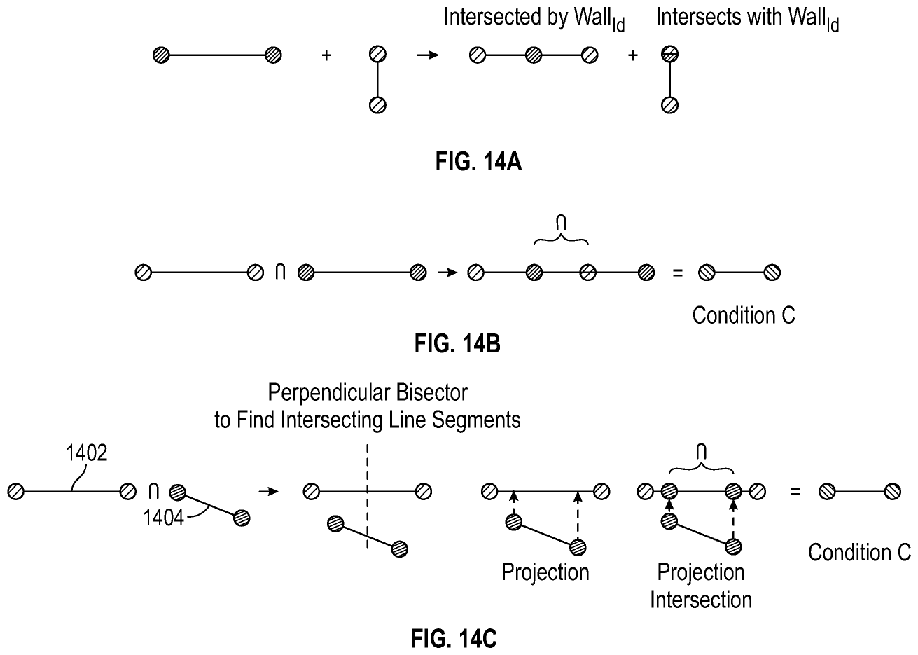

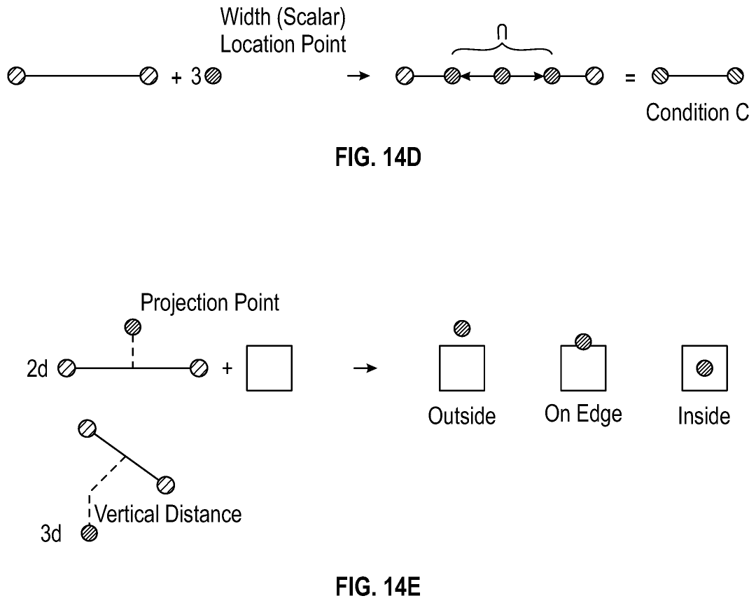

FIG. 13 illustrates an example cut sheet 1300 that can be created from a graph model of the present disclosure. The cut sheet 1300 instructs a machine or user as to how to cut a board or sheet of material. The cut sheet 1300 includes shape metadata 1302, a plan drawing 1304 showing the location of a shape, and a generated cut bar 1306. It will be understood that decimal-inch value matches the digital readout on a milling machine. Also, edge types describe an edge on a board. FIGS. 14A-14E collectively illustrate example calculations pertaining to the condition evaluations described above. For example, FIG. 14A illustrates a point on line segment algorithm that can be used to determine inside corner conditions and on edge wall end point type. FIG. 14B illustrates an intersection of two overlapping segments. In this example, condition C is a resulting line segment from a set intersection of two line segments, which define the coordinate locations of the extent of C.

FIG. 14C illustrates a condition from a line segment projection. In general, a first segment 1402 can be projected onto a second segment 1404. An intersection or union of these segments creates condition C. A line segment translation is illustrated in FIG. 14D. Given a point P in line segment S and scalar value R, the resultant condition C is the line segment defined by the translation of P along S by value R. FIG. 14E illustrates the calculation of a projected point from line segment to a polygon. For example, this process can be used to find adjacent polygons containing area specific metadata, such as ceilings, to determine vertical distance for horizontal shapes. A projection point can be located outside, on an edge of, or inside a polygonal space. The projection point can be determined in both two or three dimensions.

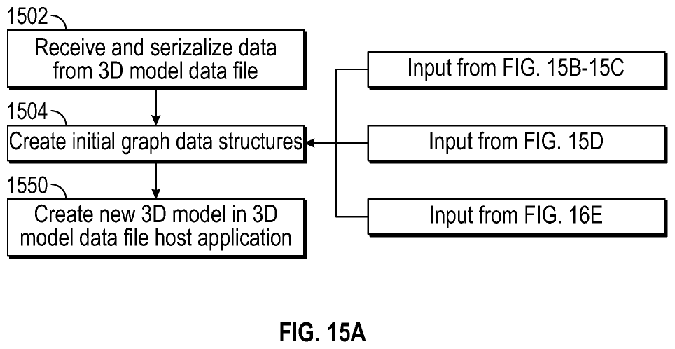

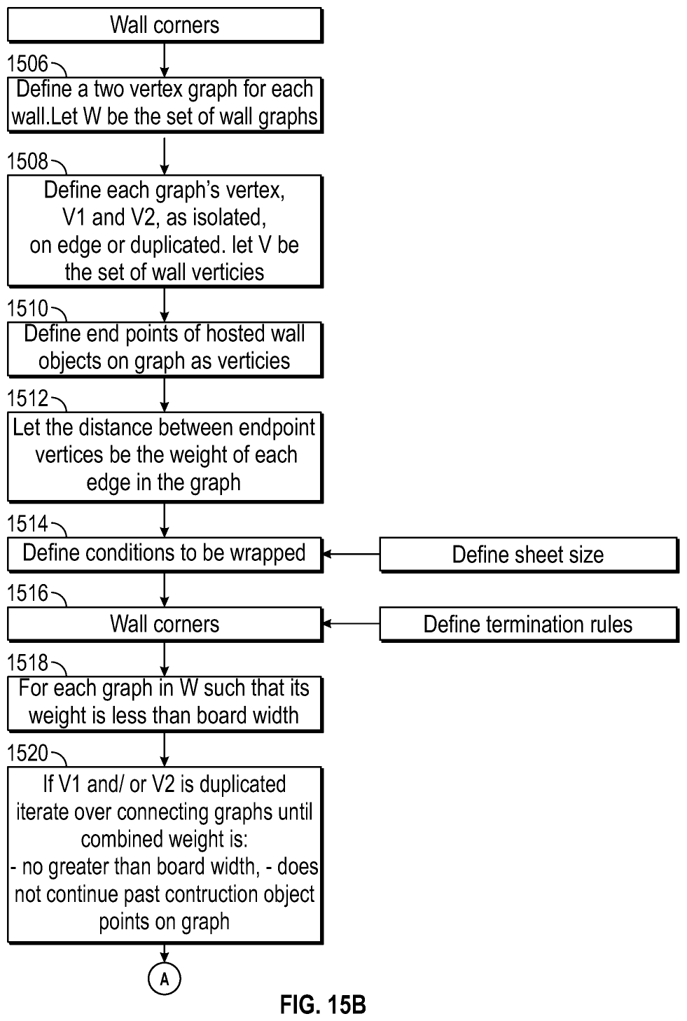

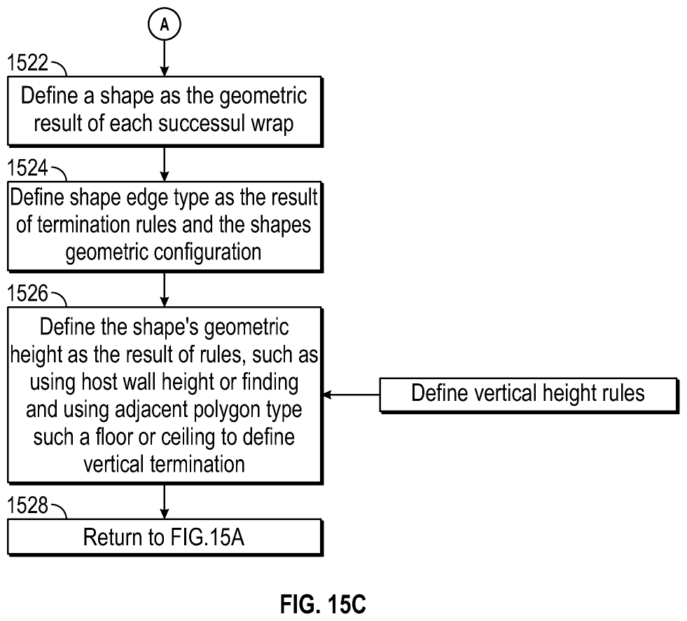

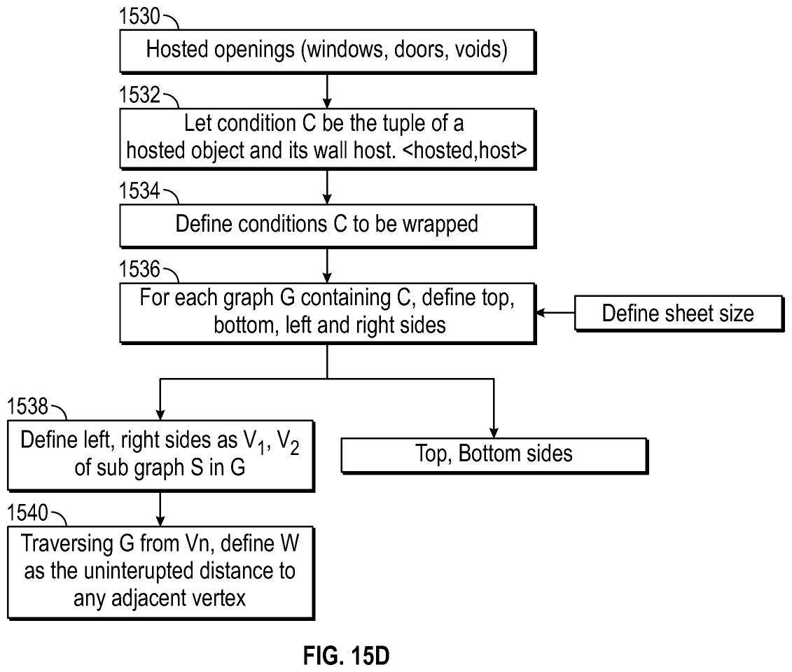

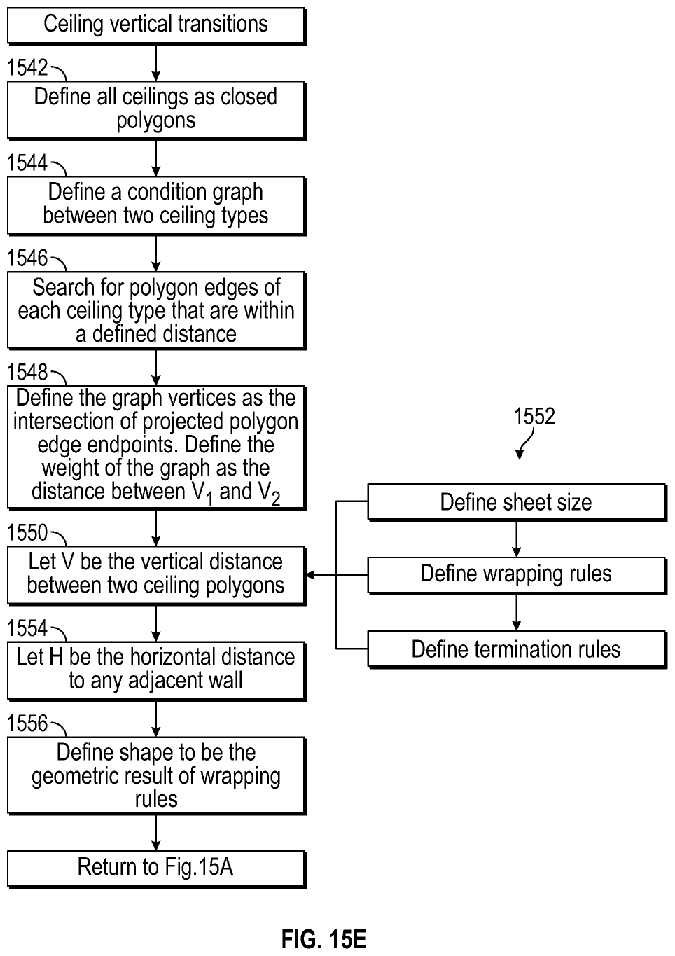

Referring now to FIGS. 15A-15E collectively, an example method is illustrated. In FIG. 15A, the method can include an initial step 1502 of receiving and serializing data from a three-dimensional (or two-dimensional, but that is covered above) model data file, such as a BIM. Next, the method can include a step of 1604 creating initial graph data structures. FIGS. 15B and 15C illustrate a sub-method of identifying wall structures. Initially, in step 1506, the method can include a step 1508 of defining a two vertex graph for each wall, and W is the set of wall graphs. In step 1508, the method can include defining each graph's vertex, V₁ and V₂, as Isolated, On Edge or Duplicated, where V is the set of wall vertices.

In step 1510, the method can include defining end points of hosted wall objects on graph as vertices. In step 1512, the method can include establishing a distance between endpoint vertices as the weight of each edge in the graph. In some embodiments, the method includes a step 1514 of define conditions to be wrapped, which can include defining a sheet size (e.g., a size of the sheet material that is to be cut).

In step 1516, wall corners are identified using defined termination rules. In step 1518, the method can include establishing, for each graph in W, a weight that is less than a board width (e.g., width of boards used to create the wall, such as a 4 foot×8 foot sheet of drywall). In step 1520, if V₁ and/or V₂ are duplicated walls, then iterate over connecting graphs until combined a weight is no greater than board width, and does not continue past construction object points on graph. This method would be used to wrap corners with physical constrains of the board.

In step 1522, the method includes defining a shape as the geometric result of each successful wrap. In some embodiments, the method includes a step 1524 of defining a shape edge type as the result of termination rules and the shapes geometric configuration. For example, edge type rules are applied such as tapered, cut, fold over, and so forth. In step 1526, the method includes defining a shape's geometric height as the result of rules, such as using host wall height or finding and using adjacent polygon type such a floor or ceiling to define vertical termination. Vertical height rules can be applied in this step. The method can return back to FIG. 15A at step 1528, in some embodiments after hosted openings and ceiling conditions are determined.

FIG. 15D illustrates a sub-method related to hosted conditions. The method can include a step 1530 of determining hosted openings (Windows, Doors, Voids). Next, in step 1532, the method includes establishing a condition C as the tuple of a hosted object and its wall host <Hosted,Host>. In step 1534, the method includes defining conditions C to be wrapped. In step 1536, the method includes defining top, bottom, left and right sides for each condition C. The sheet size used can be defined in this step. This process can also occur for top, bottom, and sides of the condition. It is understood that the top and bottom shape extents are determined by horizontal constraints, such as a floor or ceiling.

In step 1538, the method can include defining left and right sides as V₁, V₂ of sub graph S in G. The method can include a step 1540 of traversing the graph G from Vn, and defining W as the uninterrupted distance to any adjacent vertex.

Referring now to FIG. 15E, which illustrates a sub-method for evaluating ceiling vertical transitions. The method can include a step 1542 of defining all ceilings as closed polygons, along with a step 1544 of defining a condition graph between two ceiling types.

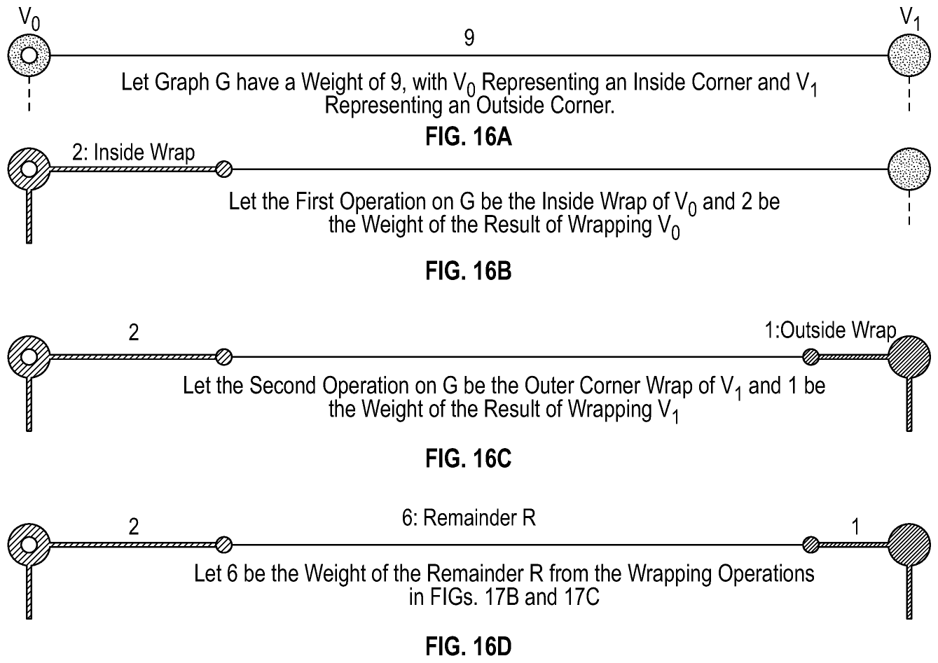

In step 1546, the method includes searching for polygon edges of each ceiling type that are within a defined distance (this uses the method in FIG. 15E). In step 1548, the method includes defining the graph vertices as the intersection of projected polygon edge endpoints, as well as defining the weight of the graph as the distance between V₁ and V₂. Also, a step 1550 includes defining VD as the vertical distance between two ceiling polygons. Step 1552 involves defining sheet sizes, wrapping rules, and termination rules (how a wall or sheet ends such as tapered, etc.) In step 1546, the method includes defining H as the horizontal distance to any adjacent wall, along with a step 1556 of defining a shape that is the geometric result of wrapping rules. Referring back briefly to FIG. 15A, the method ends with creating a new 3D model in the 3D model data file host application. This 3D model is a combination of the wall corners method of FIGS. 15A-C, the hosted openings method of FIG. 15D, and the ceiling vertical transition method of FIG. 15EC. Thus, step 1650 of FIG. 16A is the resultant output of the methods collectively.

FIGS. 16A-G collectively illustrate an example of different board shape outcomes from programmatically changing the order of operations. Adjusting the order in which the graph database is queried for shapes generates different board conditions. Referring to FIGS. 16A-E collectively, an example of setting the shape order as inside wrap FIG. 16B, outside wrap FIG. 16C, and then remainder boards FIG. 16D, leading to the formation of three unique shapes FIG. 16E. Referring to FIGS. 16F-G collectively, an example of setting the shape order as outside wrap and remainder board FIG. 16F, leads to the formation of one unique shape FIG. 16G. This ordering can be used to minimize the number of cuts needed or take into consideration other decision criteria such as minimizing wasted material.

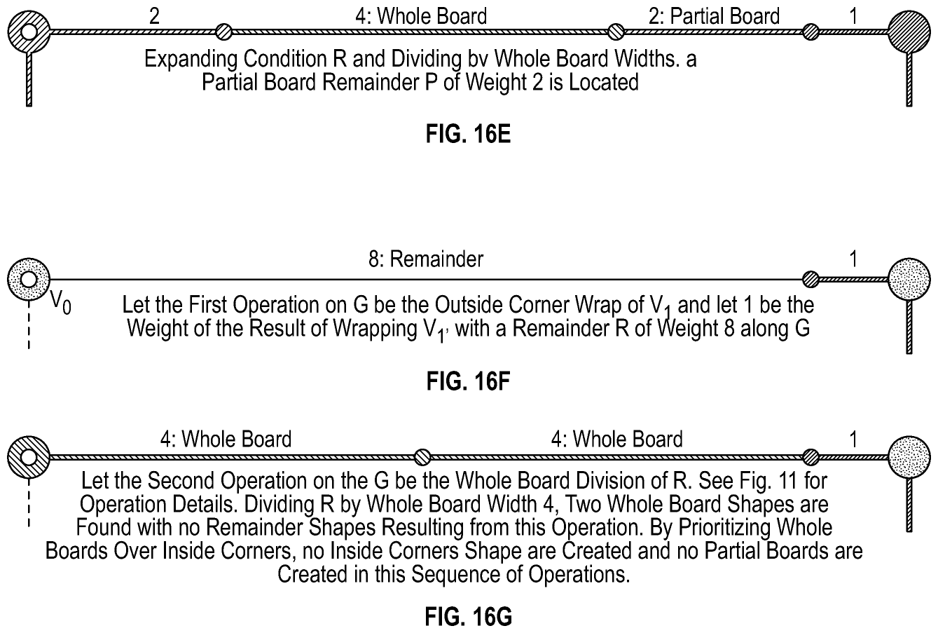

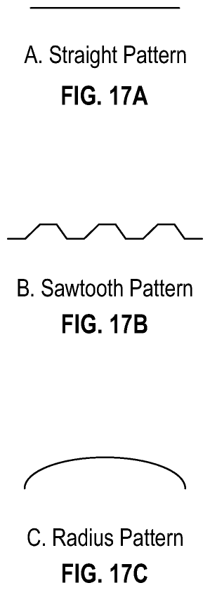

FIGS. 17A-C collectively illustrate potential patterns that could be used to cut wall boards to achieve a flush fit with surrounding conditions. Cutting instructions from the outputs of the methods contained herein can consist of both straight-line cuts, notched cuts for folded shapes, and any measure of patterned cuts. FIG. 17B and FIG. 17C respectively show examples of a patterned cut for fitting board up against a fluted metal deck and a curved pattern for other cases that may arise in architecture.

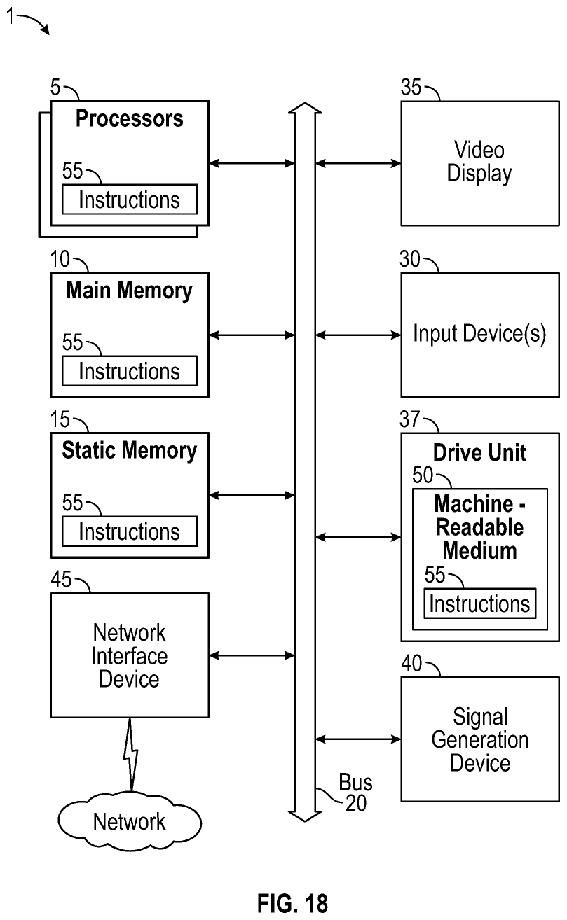

FIG. 18 is a diagrammatic representation of an example machine in the form of a computer system 1, within which a set of instructions for causing the machine to perform any one or more of the methodologies discussed herein may be executed. In various example embodiments, the machine operates as a standalone device or may be connected (e.g., networked) to other machines. In a networked deployment, the machine may operate in the capacity of a server or a client machine in a server-client network environment, or as a peer machine in a peer-to-peer (or distributed) network environment. The machine may be a personal computer (PC), a tablet PC, a set-top box (STB), a personal digital assistant (PDA), a cellular telephone, a portable music player (e.g., a portable hard drive audio device such as a Moving Picture Experts Group Audio Layer 3 (MP3) player), a web appliance, a network router, switch or bridge, or any machine capable of executing a set of instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein.

The computer system 1 includes a processor or multiple processor(s) 5 (e.g., a central processing unit (CPU), a graphics processing unit (GPU), or both), and a main memory 10 and static memory 15, which communicate with each other via a bus 20. The computer system 1 may further include a video display 35 (e.g., a liquid crystal display (LCD)). The computer system 1 may also include an alpha-numeric input device(s) 30 (e.g., a keyboard), a cursor control device (e.g., a mouse), a voice recognition or biometric verification unit (not shown), a drive unit 37 (also referred to as disk drive unit), a signal generation device 40 (e.g., a speaker), and a network interface device 45. The computer system 1 may further include a data encryption module (not shown) to encrypt data.

The drive unit 37 includes a computer or machine-readable medium 50 on which is stored one or more sets of instructions and data structures (e.g., instructions 55) embodying or utilizing any one or more of the methodologies or functions described herein. The instructions 55 may also reside, completely or at least partially, within the main memory 10 and/or within the processor(s) 5 during execution thereof by the computer system 1. The main memory 10 and the processor(s) 5 may also constitute machine-readable media.

The instructions 55 may further be transmitted or received over a network via the network interface device 45 utilizing any one of a number of well-known transfer protocols (e.g., Hyper Text Transfer Protocol (HTTP)). While the machine-readable medium 50 is shown in an example embodiment to be a single medium, the term “computer-readable medium” should be taken to include a single medium or multiple media (e.g., a centralized or distributed database and/or associated caches and servers) that store the one or more sets of instructions. The term “computer-readable medium” shall also be taken to include any medium that is capable of storing, encoding, or carrying a set of instructions for execution by the machine and that causes the machine to perform any one or more of the methodologies of the present application, or that is capable of storing, encoding, or carrying data structures utilized by or associated with such a set of instructions. The term “computer-readable medium” shall accordingly be taken to include, but not be limited to, solid-state memories, optical and magnetic media, and carrier wave signals. Such media may also include, without limitation, hard disks, floppy disks, flash memory cards, digital video disks, random access memory (RAM), read only memory (ROM), and the like. The example embodiments described herein may be implemented in an operating environment comprising software installed on a computer, in hardware, or in a combination of software and hardware.

One skilled in the art will recognize that the Internet service may be configured to provide Internet access to one or more computing devices that are coupled to the Internet service, and that the computing devices may include one or more processors, buses, memory devices, display devices, input/output devices, and the like. Furthermore, those skilled in the art may appreciate that the Internet service may be coupled to one or more databases, repositories, servers, and the like, which may be utilized in order to implement any of the embodiments of the disclosure as described herein.

The corresponding structures, materials, acts, and equivalents of all means or step plus function elements in the claims below are intended to include any structure, material, or act for performing the function in combination with other claimed elements as specifically claimed. The description of the present technology has been presented for purposes of illustration and description, but is not intended to be exhaustive or limited to the present technology in the form disclosed. Many modifications and variations will be apparent to those of ordinary skill in the art without departing from the scope and spirit of the present technology. Exemplary embodiments were chosen and described in order to best explain the principles of the present technology and its practical application, and to enable others of ordinary skill in the art to understand the present technology for various embodiments with various modifications as are suited to the particular use contemplated.

If any disclosures are incorporated herein by reference and such incorporated disclosures conflict in part and/or in whole with the present disclosure, then to the extent of conflict, and/or broader disclosure, and/or broader definition of terms, the present disclosure controls. If such incorporated disclosures conflict in part and/or in whole with one another, then to the extent of conflict, the later-dated disclosure controls.

The terminology used herein can imply direct or indirect, full or partial, temporary or permanent, immediate or delayed, synchronous or asynchronous, action or inaction. For example, when an element is referred to as being “on,” “connected” or “coupled” to another element, then the element can be directly on, connected or coupled to the other element and/or intervening elements may be present, including indirect and/or direct variants. In contrast, when an element is referred to as being “directly connected” or “directly coupled” to another element, there are no intervening elements present.

The terminology used herein is for the purpose of describing particular embodiments only and is not intended to be necessarily limiting of the disclosure. As used herein, the singular forms “a,” “an” and “the” are intended to include the plural forms as well, unless the context clearly indicates otherwise. The terms “comprises,” “includes” and/or “comprising,” “including” when used in this specification, specify the presence of stated features, integers, steps, operations, elements, and/or components, but do not preclude the presence or addition of one or more other features, integers, steps, operations, elements, components, and/or groups thereof.

Example embodiments of the present disclosure are described herein with reference to illustrations of idealized embodiments (and intermediate structures) of the present disclosure. As such, variations from the shapes of the illustrations as a result, for example, of manufacturing techniques and/or tolerances, are to be expected. Thus, the example embodiments of the present disclosure should not be construed as necessarily limited to the particular shapes of regions illustrated herein, but are to include deviations in shapes that result, for example, from manufacturing.

Aspects of the present technology are described above with reference to flowchart illustrations and/or block diagrams of methods, apparatus (systems) and computer program products according to embodiments of the present technology. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

In this description, for purposes of explanation and not limitation, specific details are set forth, such as particular embodiments, procedures, techniques, etc. in order to provide a thorough understanding of the present invention. However, it will be apparent to one skilled in the art that the present invention may be practiced in other embodiments that depart from these specific details.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” or “according to one embodiment” (or other phrases having similar import) at various places throughout this specification are not necessarily all referring to the same embodiment. Furthermore, the particular features, structures, or characteristics may be combined in any suitable manner in one or more embodiments. Furthermore, depending on the context of discussion herein, a singular term may include its plural forms and a plural term may include its singular form. Similarly, a hyphenated term (e.g., “on-demand”) may be occasionally interchangeably used with its non-hyphenated version (e.g., “on demand”), a capitalized entry (e.g., “Software”) may be interchangeably used with its non-capitalized version (e.g., “software”), a plural term may be indicated with or without an apostrophe (e.g., PE's or PEs), and an italicized term (e.g., “N+1”) may be interchangeably used with its non-italicized version (e.g., “N+1”). Such occasional interchangeable uses shall not be considered inconsistent with each other.

Also, some embodiments may be described in terms of “means for” performing a task or set of tasks. It will be understood that a “means for” may be expressed herein in terms of a structure, such as a processor, a memory, an I/O device such as a camera, or combinations thereof. Alternatively, the “means for” may include an algorithm that is descriptive of a function or method step, while in yet other embodiments the “means for” is expressed in terms of a mathematical formula, prose, or as a flow chart or signal diagram.

1. A method comprising:
receiving a building information model comprising walls, floors, and/or ceilings, hosted wall objects;
generating serialized model data;
converting the serialized model data into graph structures, the graph structures being determined by identifying wall corners, ceiling vertical transitions, horizontal constraints for ceilings and floors, and hosted conditions for each of the walls; and
generating an updated building information model from the graph structures.

2. The method according to claim 1, further comprising determining a first vertex and a second vertex for each of the walls.

3. The method according to claim 2, further comprising determining an end type for each of the first vertex and the second vertex, the end type being selected from isolated, on edge, and duplicated.

4. The method according to claim 3, further comprising iterating over connecting graphs until a combined weight is no greater than a board width of the material and does not continue past construction object points on the graph.

5. The method according to claim 4, further comprising:
projecting new vertices of a wrap onto the graph;
defining a shape as a geometric result of each successful wrap; and
defining a shape edge type as a result of termination rules and the geometric result, using edge type rules.

6. The method according to claim 5, further comprising defining a geometric height of the shape as the result of termination rules and the edge type rules, or finding and using an adjacent polygon type such a floor or ceiling to define a vertical termination using vertical height rules.

7. The method according to claim 1, further comprising defining end points of the hosted wall objects on the graph as vertices.

8. The method according to claim 7, wherein a distance between end points of the vertices are equivalent to a weight for each edge in the graph.

9. The method according to claim 1, further comprising determining conditions in the graph that for wrapping, along with a sheet size for the material.

10. The method according to claim 1, further comprising determining wall corner conditions for the walls.

11. The method according to claim 1, further comprising determining a hosted condition by determining a tuple of a hosted object and a host wall, along with wrapping conditions.

12. The method according to claim 11, further comprising determining top, bottom, left, and right sides of the hosted condition, wherein the left and right sides are further defined as vertices of a sub graph of the graph.

13. The method according to claim 12, further comprising traversing the graph from each vertex and defining an uninterrupted distance to any adjacent vertex.

14. The method according to claim 1, wherein the graph structures define, using metadata, any one or more of straight edge cuts, cut patterns, top of wall conditions, as well as types of cuts to be milled for a sheet material, wherein a cut sheet is generated for the sheet material based on the updated building information model.

15. A system comprising:
a processor; and
a memory for storing instructions, the processor executing the instructions to:
receive a building information model comprising walls and hosted wall objects;
generate serialized model data;
convert the serialized model data into graph structures, the graph structures being determined by identifying wall corners, ceiling vertical transitions, horizontal constraints for ceilings and floors, and hosted conditions for each of the walls, wherein the graph structures define any one or more of straight edge cuts, cut patterns, top of wall conditions, as well as types of cuts to be milled for a sheet material, wherein a cut sheet is generated for a sheet material based on the updated building information model; and
generate an updated building information model from the graph structures.

16. The system according to claim 15, wherein the processor is configured to:
determine a first vertex and a second vertex for each of the walls;
determine an end type for each of the first vertex and the second vertex, the end type being selected from isolated, on edge, and duplicated;
iterate over connecting graphs until a combined weight is no greater than a board width of the material and does not continue past construction object points on the graph when corners are wrapped physically.

17. The system according to claim 16, wherein the processor is configured to:
project new vertices of a wrap onto the graph;
define a shape as a geometric result of each successful wrap;
define a shape edge type as a result of termination rules and the geometric result, using edge type rules;
define a geometric height of the shape as the result of termination rules and the edge type rules, or finding and using an adjacent polygon type such a floor or ceiling to define a vertical termination using vertical height rules;
define end points of the hosted wall objects on graph as vertices, wherein a distance between end points of the vertices are equivalent to a weight for each edge in the graph.

18. The system according to claim 17, wherein the processor is configured to:
determine conditions in the graph that for wrapping, along with a sheet size for the material; and
determine wall corner conditions for the walls.

19. The system according to claim 18, wherein the processor is configured to:
determine a hosted condition by determining a tuple of a hosted object and a host wall, along with wrapping conditions;
determine top, bottom, left, and right sides of the hosted condition, wherein the left and right sides are further defined as vertices of a sub graph of the graph; and
traverse the graph from each vertex and defining an uninterrupted distance to any adjacent vertex.
